(19) United States
(12) Patent Application Publication
(10) Pub. No.: US 2026/0056242 A1
(43) Pub. Date: Feb. 26, 2026

(54) METHOD OF INSPECTING LIGHT-EMITTING ELEMENT SAMPLE, APPARATUS FOR INSPECTING LIGHT-EMITTING ELEMENT SAMPLE, METHOD OF MANUFACTURING DISPLAY DEVICE, AND ELECTRONIC DEVICE INCLUDING DISPLAY DEVICE

(71) Applicants: Samsung Display Co., Ltd., Yongin-si (KR); Korea University Research and Business Foundation, Sejong Campus, Sejong-si (KR); Dongguk University Industry-Academic Cooperation Foundation, Seoul (KR)

(72) Inventors: Jae Chul HONG, Yongin-si (KR); Seung Yoon RYU, Seoul (KR); Chul Hoon KIM, Sejong-si (KR); Jae Woo LEE, Sejong-si (KR); Chang Min LEE, Sejong-si (KR); Hyun Jae LEE, Sejong-si (KR); Ki Seok HEO, Sejong-si (KR)

(21) Appl. No.: 19/097,666

(22) Filed: Apr. 1, 2025

(30) Foreign Application Priority Data
Aug. 23, 2024 (KR) 10-2024-0113315

(51) Int. Cl. G01R 31/26; G01N 21/64; G01R 1/07

(52) U.S. Cl. CPC G01R 31/2635; G01N 21/6489; G01R 1/071

(57) ABSTRACT

A method of inspecting a light-emitting element sample, an apparatus for inspecting a light-emitting element sample, a method of manufacturing a display device, and an electronic device comprising a display device are provided. The method of inspecting the light-emitting element sample includes: acquiring electrical information and optical information on the light-emitting element sample; and analyzing the light-emitting element sample by synthesizing the electrical information and the optical information.

### CROSS-REFERENCE TO RELATED APPLICATION

The present application claims priority to and benefit of Korean Patent Application No. 10-2024-0113315, filed on Aug. 23, 2024, in the Korean Intellectual Property Office, the entire disclosure of which is incorporated herein by reference.

### BACKGROUND

### 1. Field

Embodiments of the present disclosure generally relate to a method of inspecting a light-emitting element sample, an apparatus for inspecting a light-emitting element sample, a method of manufacturing a display device, and an electronic device including a display device.

### 2. Description of the Related Art

With the growing interest in information displays, ongoing research and development efforts are focused on advancing display device technology.

To test the reliability and performance of a display device, an inspection process may be performed during the manufacturing process.

The inspection process may include inspecting a light-emitting element within the display device. To test the reliability of the light-emitting element, it may be desired or necessary to analyze various characteristics of the light-emitting element during in the inspection process.

The above information disclosed in this Background section is intended to enhance understanding of the background of the disclosure and may contain information that does not constitute prior art.

### SUMMARY

Aspects of embodiments of the present disclosure are directed toward a method of inspecting a light emitting element sample, an apparatus for inspecting a light-emitting element sample, a method of manufacturing a display device, and an electronic device including a display device, in which a light-emitting element has enhanced (e.g., excellent or suitable)light emission quality, and in which the operational reliability of the light-emitting element is improved.

Aspects of embodiments of the present disclosure are directed toward a method of inspecting a light-emitting element sample, an apparatus for inspecting a light-emitting element sample, a method of manufacturing a display device, and an electronic device including a display device, in which a degradation analysis of a light-emitting element can be performed (e.g., be thoroughly performed), and a degradation position in the light-emitting element can be detected (clearly detected) (e.g., a position of the degradation in the light-emitting element can be clearly detected).

Aspects of embodiments of the present disclosure are directed toward a method of inspecting a light-emitting element sample, an apparatus for inspecting a light-emitting element sample, a method of manufacturing a display device, and an electronic device including a display device, in which the reliability of an analysis result of an inspection operation is improved.

Aspects of embodiments of the present disclosure are directed toward a method of inspecting a light-emitting element sample, an apparatus for inspecting a light-emitting element sample, a method of manufacturing a display device, and an electronic device including a display device, in which a quantitative analysis on a characteristic of a light-emitting element is performed.

Aspects of embodiments of the present disclosure also relate to a method of inspecting a light-emitting element sample, an apparatus for inspecting a light-emitting element sample, a method of manufacturing a display device, and an electronic device including a display device, in which process efficiency is improved.

Additional aspects will be set forth in part in the description which follows and, in part, will be apparent from the description, or may be learned by practice of the presented embodiments of the disclosure.

In accordance with one or more embodiments of the present disclosure, a method of inspecting a light-emitting element sample includes: acquiring electrical information and optical information on the light-emitting element sample; and analyzing the light-emitting element sample by synthesizing the electrical information and the optical information.

In one or more embodiments, in the acquiring of the electrical information and the optical information, the electrical information and the optical information may be acquired in a same inspection process.

In one or more embodiments, the acquiring of the electrical information and the optical information may include: applying a laser to the light-emitting element sample to cause the light-emitting element sample to emit photoluminescence (PL) light; and applying a driving signal to the light-emitting element sample to acquire the electrical information of the light-emitting element sample and cause the light-emitting element sample to emit electroluminescence (EL) light. The electrical information may include a resistance and a capacitance. The laser and the driving signal may be concurrently (e.g., simultaneously) applied to the light-emitting element sample in at least a partial time period during the acquiring of the electrical information and the optical information.

In one or more embodiments, the driving signal may include a first driving signal and a second driving signal. The acquiring of the electrical information and the optical information may include: applying the first driving signal to the light-emitting element sample within a first time period; applying the second driving signal to the light-emitting element sample within a second time period after the first time period and the second time period including a first sub-time period and a second sub-time period; and applying the laser to the light-emitting element sample within the second sub-time period.

In one or more embodiments, the acquiring of the electrical information and the optical information may include acquiring a PL spectrum of a light intensity according to a time and a wavelength based on the PL light.

In one or more embodiments, the method may further include performing an aging process on the light-emitting element sample.

In one or more embodiments, the acquiring of the electrical information and the optical information may include: acquiring first electrical information on the light-emitting element sample and forming a first equivalent circuit corresponding to the first electrical information, before the performing of the aging process; and acquiring second electrical information on the light-emitting element sample and forming a second equivalent circuit corresponding to the second electrical information, after the performing of the aging process, and wherein the analyzing of the light-emitting element sample includes analyzing whether degradation of the light-emitting element sample has occurred.

In one or more embodiments, the acquiring of the electrical information and the optical information may include: acquiring information on the light-emitting element sample based on first electroluminescence (EL) light emitted from the light-emitting element sample before the performing of the aging process; and acquiring information on the light-emitting element sample based on second EL light emitted from the light-emitting element sample after the performing of the aging process. The analyzing of the light-emitting element sample may include analyzing current efficiency and quantum efficiency of the light-emitting element sample.

In one or more embodiments, the acquiring of the electrical information and the optical information may include: acquiring a first photoluminescence (PL) spectrum based on first PL light emitted from the light-emitting element sample before the performing of the aging process; and acquiring a second PL spectrum based on second PL light emitted from the light-emitting element sample after the performing of the aging process. The first PL spectrum and the second PL spectrum may represent light intensities according to times and wavelengths of the first PL light and the second PL light, respectively. The analyzing of the light-emitting element sample may include specifying a target layer degraded in the light-emitting element sample.

In one or more embodiments, the analyzing of the light-emitting element sample may include acquiring quantitative data representing a degree to which the light-emitting element sample is degraded.

In one or more embodiments, the acquiring of the electrical information and the optical information may include separating different light components respectively from the first PL spectrum and the second PL spectrum to acquire graphs respectively corresponding to the light components.

In one or more embodiments, the light-emitting element sample may include an electron transport layer, a hole transport layer, and a light-emitting layer between the electron transport layer and the hole transport layer. The light components may include a target exciton generated inside the light-emitting layer and a parasitic exciton generated at a surface of the light-emitting layer.

In one or more embodiments, the light-emitting layer may include a host and a dopant. The analyzing of the light-emitting element sample may include: predetermining a dopant wavelength of dopant light provided by the dopant; and determining a degradation degree of the light-emitting element sample based on a light intensity variation in the dopant wavelength in the graphs.

In accordance with one or more embodiments of the present disclosure, an apparatus for inspecting a light-emitting element sample includes: a light source part configured to output a laser to the light-emitting element sample; a sample accommodating part configured to accommodate the light-emitting element sample therein; and a sample analysis part configured to analyze the light-emitting element sample, and wherein the sample analysis part includes: an electrical analysis part configured to acquire electrical information on the light-emitting element sample; an optical analysis part configured to acquire optical information on the light-emitting element sample; and a synthesis analysis part configured to acquire synthesis analysis information by synthesizing the electrical information and the optical information.

In one or more embodiments, the electrical information may include a resistance and a capacitance of the light-emitting element sample. The electrical analysis part may provide a driving signal to the light-emitting element sample to cause the light-emitting element sample to emit electroluminescence (EL) light, and may apply an alternating current. (AC) signal to the light-emitting element sample to acquire the electrical information.

In one or more embodiments, the optical information may include information on EL light and information on photoluminescence (PL) light. The optical analysis part may analyze a time for which the EL light is output, a light intensity according to a spectrum, and/or the like, and may analyze a time for which the PL light is output, a light intensity according to a spectrum, and/or the like, respectively.

In one or more embodiments, electrical analysis part may be an LCR meter (which measures inductance (L), capacitance (C), and resistance (R)), the optical analysis part may be a spectrometer, and the light-emitting element sample may be an organic light-emitting diode.

In one or more embodiments, the apparatus may further include a power supply part configured to supply a power signal to the light-emitting element sample. The sample accommodating part may be a dark shielding box. The laser may be pulse input light in a unit of picoseconds (pa) or femtoseconds (fs).

In accordance with one or more embodiments of the present disclosure, a method of manufacturing a display device includes: applying a light-emitting element on a mother substrate; performing a first inspection step (e.g., act or task) after the applying of the light-emitting element, the first inspection step (e.g., act or task) including performing an inspection process on the light-emitting element; forming an encapsulation layer on the light-emitting element; performing a second inspection step (e.g., act or task) after the forming of the encapsulation layer, the second inspection step (e.g., act or task) including performing an inspection process on the light-emitting element; and cutting the mother substrate, wherein each of the first inspection step (e.g., act or task) and the second inspection step (e.g., act or task) includes a unit operation, and wherein the unit operations each include: acquiring electrical information and optical information on the light-emitting element; and analyzing the light-emitting element by synthesizing the electrical information and the optical information.

In one or more embodiments, the electrical information may include a resistance and a capacitance of the light-emitting element. The optical information may include information on electroluminescence (EL) light provided by the light-emitting element and information on photoluminescence (PL) light provided by the light-emitting element. In the acquiring of the electrical information and the optical information, the electrical information and the optical information may be acquired in a same inspection process.

In accordance with one or more embodiments of the present disclosure, an electronic device includes: a processor configured to provide input image data; a display device configured to display an image based on the input image data, the display device including sub-pixel areas and manufactured by the aforementioned method; and a power supply configured to supply power to the display device.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure. In the drawings:

FIG. 1 is a schematic block diagram illustrating an apparatus for inspecting a light-emitting element sample, according to one or more embodiments of the present disclosure.

FIG. 2 is a flowchart illustrating a method of inspecting a light-emitting element sample, according to one or more embodiments of the present disclosure.

FIG. 3 is a schematic view illustrating an apparatus for inspecting a light-emitting element sample, according to one or more embodiments of the present disclosure.

FIG. 4 is a diagram illustrating a driving signal supplied to a light-emitting element sample, according to one or more embodiments of the present disclosure.

FIG. 5 is a flowchart illustrating a method of inspecting a light-emitting element sample, according to one or more embodiments of the present disclosure.

FIG. 6 is a diagram schematically illustrating a light-emitting element sample and an equivalent circuit thereof, according to one or more embodiments of the present disclosure.

FIG. 7 is a graph illustrating an analysis result of electroluminescence (EL) light, according to one or more embodiments of the present disclosure.

FIG. 8-12 show graphs illustrating results obtained by analyzing photoluminescence (PL) light, according to one or more embodiments of the present disclosure.

FIG. 13 is a flowchart illustrating a method of manufacturing a display device, according to one or more embodiments of the present disclosure.

FIG. 14 is a schematic plan view illustrating at least some process steps of the method shown in FIG. 13, according to one or more embodiments of the present disclosure.

FIG. 15 is a schematic block diagram illustrating an electronic device including a display device, according to one or more embodiments of the present disclosure.

FIG. 16 is a schematic diagram illustrating an example where the electronic device of FIG. 15 is implemented as a smartphone, according to one or more embodiments of the present disclosure.

FIG. 17 is a schematic diagram illustrating an example where the electronic device of FIG. 15 is implemented as a tablet computer, according to one or more embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

As used herein, the singular forms “a,” “an” and “the” are intended to include the plural forms as well, unless the context clearly indicates otherwise.

It will be further understood that the terms “comprises,” “comprising,” “includes,” “including,” “have,” and “having,” when used in this specification, specify the presence of the stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

It will be understood that when an element, such as an area, layer, film, region or portion, is referred to as being “on” or “connected to” another element, it can be directly on or connected to the other element, or one or more intervening elements may be present. In contrast, when an element or layer is referred to as being “directly on,” “directly connected to”, or “immediately adjacent to” another element or layer, there are no intervening elements or layers present. In addition, it will also be understood that when an element is referred to as being “between” two elements, it can be the only element between the two elements, or one or more intervening elements may also be present. Further, an expression that an element such as a layer, region, substrate or plate is placed “on” or “above” another element indicates not only a case where the element is placed “directly on” or “just above” the other element, but also a case where a further element is interposed between the element and the other element. In contrast, an expression that an element such as a layer, region, substrate or plate is placed “beneath” or “below” another element indicates not only a case where the element is placed “directly beneath” or “just below” the other element, but also a case where a further element is interposed between the element and the other element.

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below”and “under”can encompass both an orientation of above and below. The device may be otherwise oriented (e.g., rotated 90 degrees or at other orientations) and the spatially relative descriptors used herein should be interpreted accordingly.

Unless otherwise noted, like reference numerals denote like elements throughout the attached drawings and the written description, and thus, duplicative descriptions thereof may not be provided. In the drawings, the relative sizes of elements, layers, and regions may be exaggerated for clarity.

As used herein, the term “and/or” includes any and all combinations of one or more of the associated listed items. As used herein, the terms “use,” “using,” and “used” may be considered synonymous with the terms “utilize,” “utilizing,” and “utilized,”respectively.

The present disclosure generally relates to a method of inspecting a light-emitting element sample, an apparatus for inspecting a light-emitting element sample, a method of manufacturing a display device, and an electronic device including a display device. Hereinafter, a method of inspecting a light-emitting element sample, an apparatus for inspecting a light-emitting element sample, a method of manufacturing a display device, and an electronic device including a display device in accordance with one or more embodiments of the present disclosure will be described with reference to the accompanying drawings.

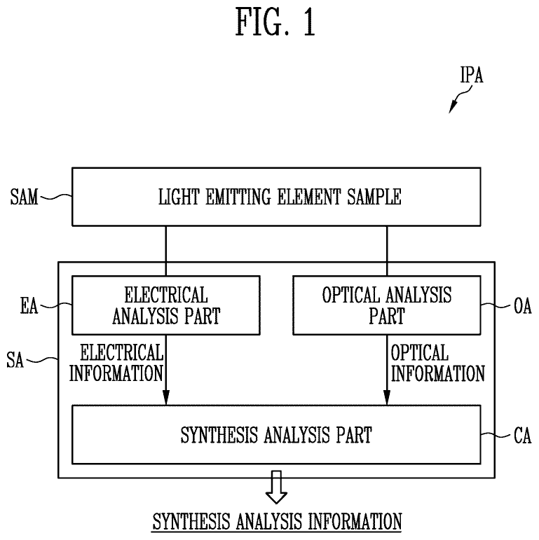

An apparatus IPA of a light-emitting element sample and a method of inspecting a light-emitting element sample SAM, using the apparatus IPA in accordance with one or more embodiments of the present disclosure will be described with reference to FIGS. 1 to 4.

FIG. 1 is a schematic block diagram illustrating an apparatus IPA for inspecting a light-emitting element sample SAM in accordance with one or more embodiments of the present disclosure.

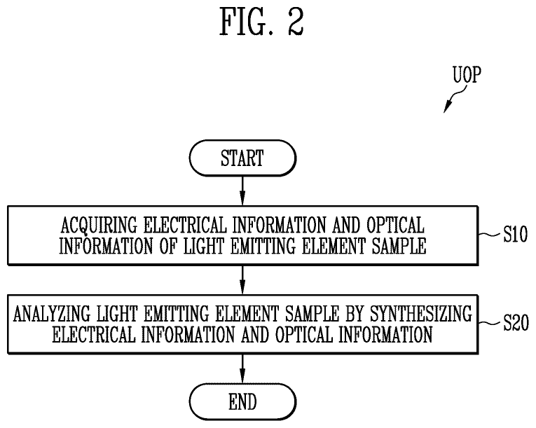

FIG. 2 is a flowchart illustrating a method of inspecting a light-emitting element sample SAM in accordance with one or more embodiments of the present disclosure. FIG. 2 illustrates a unit operation UOP of a method of inspecting a light-emitting element sample SAM. For example, in order to perform a process of inspecting the light-emitting element sample SAM, the unit operation UOP may perform each of the different process steps during a process of manufacturing a display device.

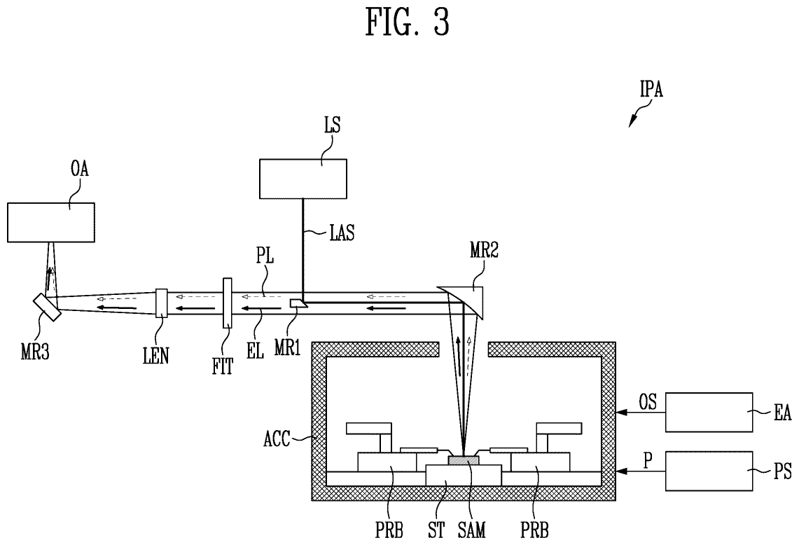

FIG. 3 is a schematic view illustrating an apparatus for inspecting a light-emitting element sample in accordance with one or more embodiments of the present disclosure. FIG. 3 illustrates a plurality of devices for performing a method of inspecting a display device and a light-emitting element sample SAM in accordance with one or more embodiments of the present disclosure. In FIG. 3, optical paths are indicated by an arrow, a solid line, and/or the like between components.

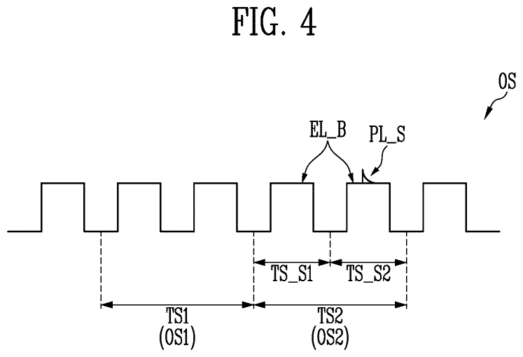

FIG. 4 is a diagram illustrating a driving signal supplied to a light-emitting element sample. FIG. 4 illustrates a driving signal, and illustrates a voltage intensity of an alternating current (AC) signal according to time elapsing (e.g., in different time periods, as described in more detail below).

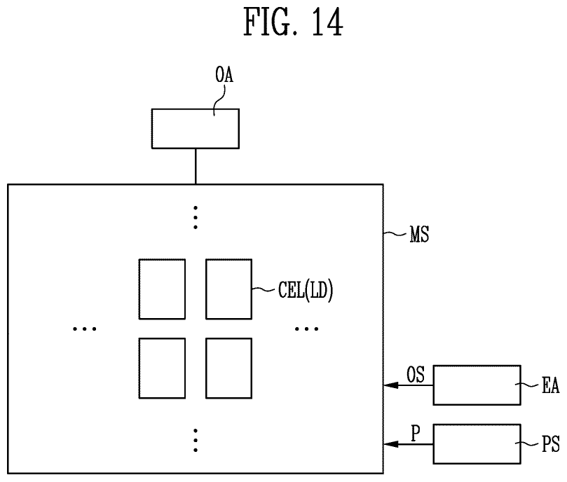

In accordance with one or more embodiments, a method of inspecting a light-emitting element sample for performing a process of inspecting a light source (e.g., a light-emitting element LD (see, e.g., FIG. 14)) applied to a display device is disclosed. A light-emitting element sample SAM may be a light-emitting element including a plurality of layers. The light-emitting element sample SAM may be an organic light-emitting diode. In one or more embodiments, the light-emitting element sample SAM may be, as in the example of the organic light-emitting diode, a final target product manufactured to operate normally. For example, according to the method of inspecting the light-emitting element sample SAM in accordance with one or more embodiment of the present disclosure, nondestructive analysis on the organic light-emitting diode may be possible. However, the present disclosure is not necessarily limited to the above examples. In one or more embodiments, the light-emitting element sample SAM may be a light-emitting diode including an inorganic material.

In one or more embodiments, the process of inspecting the light-emitting element sample SAM (or method of inspecting the light-emitting element sample SAM) (e.g., the unit operation UOP) may include the step (e.g., act or task) S10 of acquiring electrical information and optical information of a light-emitting element sample and the step (e.g., act or task) S20 of analyzing the light-emitting element sample by synthesizing the electrical information and the optical information (e.g., by performing a combined analysis utilizing both the electrical and optical information in tandem).

In one or more embodiments, in the step (e.g., act or task) S10 of acquiring the electrical information and optical information of the light-emitting element sample, an electrical analysis part EA may acquire electrical information based on an electrical signal provided from the light-emitting element sample SAM, and an optical analysis part OA may acquire optical information based on an optical signal provided from the light-emitting element sample SAM.

In one or more embodiments, in the step (e.g., act or task) S20 of analyzing the light-emitting element sample by synthesizing (e.g., combining) the electrical information and the optical information, a sample analysis part SA may acquire the synthesized analysis information (e.g., the synthesis analysis information) and a state and/or the like of the light-emitting element sample SAM can be determined from this synthesized information originating from the light-emitting element sample SAM.

The apparatus IPA may include the sample analysis part SA, and the sample analysis part SA may include the electrical analysis part EA, the optical analysis part OA, and a synthesis analysis part CA.

The electrical analysis part EA may acquire electrical information, based on an electrical signal provided from the light-emitting element sample SAM. The electrical information may include a capacitance of the light-emitting element sample SAM. The electrical information may include a resistance of the light-emitting element sample SAM. The electrical information may include an impedance of the light-emitting element sample SAM.

The electrical analysis part EA may include one or more suitable devices generally available and/or generally utilized in the art that can measure a capacitance, a resistance, and/or the like of the light-emitting element sample SAM. For example, the electrical analysis part EA may be an LCR meter (which measures inductance (L), capacitance (C), and resistance (R)). However, the present disclosure is not limited thereto. In one or more embodiments, the electrical analysis part EA may include one or more suitable impedance analyzers.

The electrical analysis part EA may acquire electrical information on the light-emitting element sample SAM, and provide a driving signal OS to the light-emitting element sample SAM such that the light-emitting element sample SAM outputs electroluminescence (EL) light EL.

The capacitance, resistance, and/or the like of the light-emitting element sample SAM may be changed according to physical/chemical characteristics of the light-emitting element sample SAM. Therefore, the capacitance, resistance, and/or the like of the light-emitting element sample SAM may be changed if (e.g., when) the light-emitting element sample SAM further includes an unintended impurity or if (e.g., when) sides forming the light-emitting element sample SAM has an unintended thickness. Accordingly, a defect of the light-emitting element sample SAM may be determined based on the electrical information of the light-emitting element sample SAM.

The electrical information (e.g., the capacitance and the resistance) of the light-emitting element sample SAM may be measured as an alternating current (AC) signal is provided to the light-emitting element sample SAM. In one or more embodiments, if (e.g., when) the light-emitting element sample SAM is an organic light-emitting diode, the electrical information on the light-emitting element sample SAM may be acquired before an encapsulation process on the light-emitting element sample SAM is performed.

The optical analysis part OA may acquire optical information, based on an optical signal provided from the light-emitting element sample SAM. The optical information may include information on EL light. The optical information may include information on photoluminescence (PL) light PL.

The optical analysis part OA may include one or more suitable devices generally available and/or generally utilized in the art, which can analyze light output from the light-emitting element sample SAM. For example, the optical analysis part OA may be a spectrometer, a spectrophotometer, and/or the like.

The EL light EL provided by the light-emitting element sample SAM may be generated based on an electroluminescent effect as the driving signal OS (e.g., a driving voltage) is applied to the light-emitting element sample SAM. Accordingly, the optical analysis part OA may analyze a time during which the EL light EL is applied, a light intensity according to a spectrum, and/or the like, and analyze efficiency, a color coordinate, brightness, and/or the like of the light-emitting element sample SAM.

The PL light PL provided by the light-emitting element sample SAM may be generated based on a photoluminescent effect as a laser LAS is applied to the light-emitting element sample SAM. Accordingly, the optical analysis part OA may analyze a time during which the PL light PL is applied, a light intensity according to a spectrum, and/or the like, and analyze a material characteristic and/or the like of the light-emitting element sample SAM.

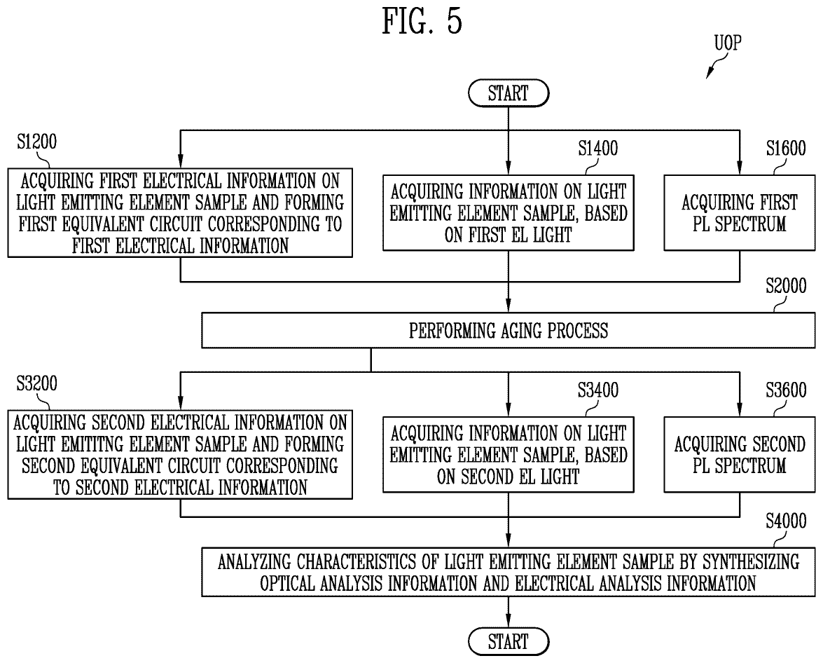

The sample analysis part SA may acquire synthesis analysis information by synthesizing the acquired electrical information and the acquired optical information. In one or more embodiments, the synthesis analysis part CA may provide synthesis analysis information by synthesizing electrical information and optical information. For example, the electrical information and the optical information may be acquired in a same inspection process, and electrical information and optical information, which are acquired in a same process, may be complementarily interpreted. The synthesis analysis part CA may determine the optical information with reference to the electrical information, determine the electrical information with reference to the optical information, and derive an analysis result of the light-emitting element sample SAM, which has high reliability, with reference to the electrical information and the optical information. Additional details related to this will be described later with reference to FIG. 5.

With respect to FIGS. 3 and 4, a structure of the apparatus IPA for performing the method of inspecting the light-emitting element sample SAM in accordance with one or more embodiments of the present disclosure is disclosed. For convenience of description, in FIG. 3, the laser LAS is indicated by a relatively thick solid line, EL light is indicated by a relatively heavy solid-line arrow, and PL light is indicated by a relatively light dotted-line arrow.

The apparatus IPA may further include a sample accommodating part ACC.

The sample accommodating part ACC may form a space in which a light-emitting element sample SAM, a stage ST, a probe PRB, and/or the like are accommodated during an inspecting process. The sample accommodating part ACC may block or reduce external light.

In one or more embodiments, the sample accommodating part ACC may be a dark shielding box. The sample accommodating part ACC may minimize or reduce the influence of external light in the process of inspecting the light-emitting element sample SAM.

In one or more embodiments, the sample accommodating part ACC may include a laser port through which the laser LAS can be applied. The sample accommodating part ACC may include a path through which a line for supplying a driving signal OS and for supplying a power signal P is formed.

The apparatus IPA may further include the stage ST.

The stage ST may form a base on which the light-emitting element sample SAM is arranged during the process of inspecting the light-emitting element sample SAM.

The apparatus IPA may further include the probe PRB.

The probe PRB may be electrically connected to the light-emitting element sample SAM. The probe PRB may supply the driving signal OS, the power signal P, and/or the like to the light-emitting element sample SAM. As the probe PRB applies the driving signal OS to the light-emitting element sample SAM, electrical information on the light-emitting element sample SAM may be output. As the probe PRB applies the driving signal OS to the light-emitting element sample SAM, the light-emitting element sample SAM may output EL light EL, and accordingly, optical information on the light-emitting element sample SAM may be output.

The IPA may further include a power supply part PS.

The power supply part PS may supply power to the light-emitting element sample SAM so the light-emitting element sample SAM can provide the EL light and the electrical information on the light-emitting element sample SAM can be acquired. As the power signal P and the driving signal OS are supplied to the light-emitting element sample SAM during the process of inspecting the light-emitting element sample SAM, the light-emitting element sample SAM may provide the EL light EL, and a capacitance, a resistance, and/or the like of the light-emitting element sample SAM may be measured. In one or more embodiments, the power supply part PS may be a power supply.

The apparatus IPA may further include a light source part LS.

The light source part LS may output the laser LAS provided to the light-emitting element sample SAM through the laser port (e.g., an opening in the sample accommodating part ACC) so the light-emitting element sample SAM can provide the PL light PL. The laser LAS may be pulse input light in a unit of picoseconds (pa) or femtoseconds (fs). The laser LAS may have a wavelength of 300 nm to 520 nm, but the present disclosure is not limited thereto.

The apparatus IPA may further include first to third mirrors MR1 to MR3, a filter part FIT, and a lens part LEN.

In one or more embodiments, the laser LAS provided by the light source part LS may be provided to the laser port through the first and second mirrors MR1 and MR2, and applied to the light-emitting element sample SAM. Accordingly, the light-emitting element sample SAM may provide PL light PL. In one or more embodiments, in a same inspection process, because the light-emitting element sample SAM is electroluminescent, the light-emitting element sample SAM may provide EL light EL together with the PL light PL. The PL light PL and the EL light EL may be provided to the optical analysis part OA through the second mirror MR2, the filter part FIT, the lens part LEN, and the third mirror MR3. In one or more embodiments, the filter part FIT may block or reduce light in some undesirable and/or unnecessary wavelength bands, and the lens part LEN may condense the PL light PL and the EL light EL.

In one or more embodiments, in conjunction with FIG. 4, the driving signal OS may be supplied to the light-emitting element sample SAM such that the EL light EL is output from the light-emitting element sample SAM, and the electrical information on the light-emitting element sample SAM is acquired. According to one or more embodiments, an intensity of a voltage in a time period (e.g., a partial time period) in which the driving signal OS is supplied is illustrated in FIG. 4.

The driving signal OS may be an AC signal. The driving signal OS may be an electrical signal for allowing the light-emitting element sample SAM to be electroluminescent. The driving signal OS may be provided in the form of an AC signal input as a pulse input.

The driving signal OS may have a set or predetermined amplitude and a set or predetermined frequency. The amplitude and frequency of the driving signal OS are not limited to a specific example.

The driving signal OS may include a first driving signal OS1 supplied within a first time period TS1 and a second driving signal OS2 supplied within a second time period TS2.

In one or more embodiments, the second time period TS2 may be after the first time period TS1. For example, the second time period TS2 may be immediately after the first time period TS1.

The light-emitting element sample SAM may be supplied with the first driving signal OS1 within the first time period TS1, and electrical information on the light-emitting element sample SAM may be acquired (e.g., analyzed) within the first time period TS1. For example, as the first driving signal OS1 is applied to the light-emitting element sample SAM within the first time period TS1, a resistance and a capacitance in the light-emitting element sample SAM may be measured.

The light-emitting element sample SAM may be supplied with the second driving signal OS within the second time period TS2. The light-emitting element sample SAM may output EL light EL within the second time period TS2. For example, efficiency, a color coordinate, brightness, and/or the like of the light-emitting element sample SAM may be analyzed based on the EL light EL of the light-emitting element sample SAM, which is output within the second time period TS2.

The light-emitting element sample SAM is supplied with the second driving signal OS2 within the second time period TS2, and may be further applied with laser LAS in a portion of (e.g., a partial period within) the second time period TS2. Accordingly, the light-emitting element sample SAM may output PL light PL.

The second time period TS2 may include a first sub-time period TS_S1 and a second sub-time period TS_S2. In one or more embodiments, the second sub-time period TS_S2 may be after the first sub-time period TS_S1. For example, the second sub-time period TS_S2 may be immediately after the first sub-time period TS_S1. In one or more embodiments, the first sub-time period TS_S1 may be after the first time period TS1. For example, the first sub-time period TS_S1 may be immediately after the first time period TS1.

The light-emitting element sample SAM may be supplied with the second driving signal OS2 within the first sub-time period TS_S1, and may not be applied with the laser LAS. Accordingly, the light-emitting element sample SAM may output the EL light EL as the second driving signal OS2 having an intensity of a background signal EL_B is applied within the first sub-time period TS_S1.

The light-emitting element sample SAM may be supplied with the second driving signal OS2 within the second sub-time period TS_S2, and may be applied with the laser LAS. Accordingly, the light-emitting element sample SAM may concurrently (e.g., simultaneously) output the EL light EL as the second driving signal OS2 having the intensity of the background signal EL_B within the second sub-time period TS_S2 and may output the PL light PL as the laser LAS is applied within the second sub-time period TS_S2. In one or more embodiments, because the PL light PL along with the EL light EL are output within the second sub-time period TS_S2, it may be interpreted that an intensity of the second driving signal OS2 for allowing the light-emitting element sample SAM to emit light within the second sub-time period TS_S2 has an intensity obtained by adding up the intensity of the background signal EL_B and an intensity of a emission signal PL_S.

In accordance with one or more embodiments, if (e.g., when) the laser LAS is not applied, the intensity of the second driving signal OS may be measured within the first sub-time period TS_S1, and therefore, the emission signal PL_S may be quantitatively acquired (e.g., analyzed or measured) within the second sub-time period TS_S2. Accordingly, data having a light intensity according to a time and a spectrum may be acquired using the PL light PL output together with the EL light EL within the second sub-time period TS_S2.

Consequently, in a time period within a constant range, analysis of the electrical information of the light-emitting element sample SAM, analysis based on the EL light EL, and analysis based on the PL light PL can be concurrently (e.g., simultaneously) performed, and characteristics of the light-emitting element sample SAM can be more thoroughly analyzed based on data having improved reliability.

In other words, within a defined time period, a comprehensive analysis of the light-emitting element sample SAM can be conducted. This includes the simultaneous or concurrent performance of electrical information analysis, electroluminescence (EL) light analysis, and photoluminescence (PL) light analysis. The electrical information analysis involves measuring parameters such as capacitance, resistance, and impedance of the light-emitting element sample SAM. The EL light analysis focuses on evaluating the efficiency, color coordinates, brightness, and other optical characteristics of the light-emitting element sample SAM when it emits light due to the applied driving signal OS. The PL light analysis involves assessing the material characteristics and other properties of the light-emitting element sample SAM when it emits light in response to the applied laser LAS.

By synthesizing the electrical and optical information obtained from these analyses, the sample analysis part SA can generate highly reliable synthesis analysis information. This synthesized data allows for a more thorough understanding of the characteristics and performance of the light-emitting element sample SAM. The combined analysis ensures that any defects or variations in the light-emitting element sample SAM can be accurately identified and characterized, leading to improved reliability and performance of the final display device.

A method of inspecting a light-emitting element sample in accordance with one or more embodiments of the present disclosure will be described in more detail with reference to FIGS. 5 to 14. For convenience of description, descriptions of portions overlapping with the above-described portion may be simplified or may not be repeated.

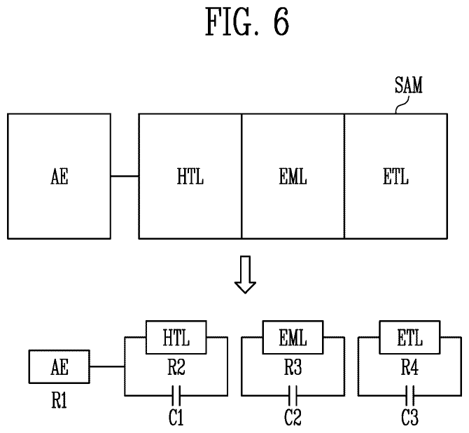

First, a method of inspecting a light-emitting element sample, which is accompanied with an aging process, in accordance with one or more embodiments of the present disclosure will be described with reference to FIGS. 5 and 6.

FIG. 5 is a flowchart illustrating a method of inspecting a light-emitting element sample in accordance with one or more embodiments of the present disclosure. FIG. 6 is a diagram schematically illustrating a light-emitting element sample and an equivalent circuit thereof in accordance with one or more embodiments of the present disclosure.

Referring to FIG. 5, in one or more embodiments, the method of inspecting the light-emitting element sample SAM (e.g., the unit operation UDP) may include an aging process and a step (e.g., act or task) of acquiring electrical information and optical information before/after the aging process.

The method of inspecting the light-emitting element sample SAM (e.g., the unit operation UDP) may include the step (e.g., act or task) S1200 of acquiring first electrical information on a light-emitting element sample SAM and forming a first equivalent circuit corresponding to the first electrical information, the step (e.g., act or task) S1400 of acquiring information on the light-emitting element sample based on first EL light, and the step (e.g., act or task) S1600 of acquiring a first PL spectrum.

The method of inspecting the light-emitting element sample SAM (e.g., the unit operation UDP) may further include step (e.g., act or task) S2000 of performing an aging process.

The method of inspecting the light-emitting element sample SAM (e.g., the unit operation UDP) may further include the step (e.g., act or task) S3200 of acquiring second electrical information on the light-emitting element sample and forming a second equivalent circuit corresponding to the second electrical information, the step (e.g., act or task) S3400 of acquiring information on the light-emitting element sample based on second EL light, and the step (e.g., act or task) S3600 of acquiring a second PL spectrum.

The method of inspecting the light-emitting element sample SAM (e.g., the unit operation UDP) may further include the step (e.g., act or task) S4000 of analyzing characteristics of the light-emitting element sample by synthesizing optical analysis information and electrical analysis information.

In one or more embodiments, the step (e.g., act or task) S1200 of acquiring the first electrical information on the light-emitting element sample and forming the first equivalent circuit corresponding to the first electrical information, the step (e.g., act or task) S1400 of acquiring the information on the light-emitting element sample based on the first EL light, and the step (e.g., act or task) S1600 of acquiring the first PL spectrum may be performed in substantially the same process within a constant time period. Accordingly, a process time desired or required in an inspection on a light-emitting element sample SAM can be reduced.

In one or more embodiments, in the step (e.g., act or task) S1200 of acquiring the first electrical information on the light-emitting element sample and forming the first equivalent circuit corresponding to the first electrical information, electrical information of the light-emitting element sample SAM may be analyzed.

For example (see, e.g., FIG. 6), the light-emitting element sample SAM may be an organic light-emitting diode, and include a hole transport layer HTL, a light-emitting layer EML, and an electron transport layer ETL. In one or more embodiments, the hole transport layer HTL of the light-emitting element sample SAM may be electrically connected to an anode electrode AE.

In the step (e.g., act or task) S1200, if (e.g., when) a first driving signal is supplied to the light-emitting element sample SAM, the electrical analysis part EA may measure a resistance and a capacitance of the light-emitting element sample SAM. In one or more embodiments, measured data may be analyzed according to an equivalent circuit corresponding to the light-emitting element SAM. For example, the anode electrode AE, the hole transport layer HTL, the light-emitting layer EML, and the electron transport layer ETL may sequentially form one circuit. In one or more embodiments, the anode electrode AE may have a first resistance R1, the hole transport layer HTL may have a second resistance R2 and a first capacitance C1, the light-emitting layer EML may have a third resistance R3 and a second capacitance C2, and the electron transport layer ETL may have a fourth resistance R4 and a third capacitance C3. Accordingly, measured data may correspond to an acquired first equivalent circuit, and the anode electrode AE, the hole transport layer HTL, the light-emitting layer EML, and the electron transport layer ETL may have a set or predetermined resistance and/or a set or predetermined capacitance.

In one or more embodiments, in the step (e.g., act or task) S1400 of acquiring the information on the light-emitting element sample based on the first EL light, optical information of the light-emitting element sample SAM may be analyzed based on EL light EL output from the light-emitting element sample SAM.

In this step (e.g., act or task) S1400, the light-emitting element sample SAM may output the EL light EL, and the EL light EL may be analyzed, so that current efficiency for each luminance, and quantum efficiency with respect to light emitted from the light-emitting element sample SAM may be analyzed.

In one or more embodiments, in the step (e.g., act or task) S1600 of acquiring the first PL spectrum, the optical information of the light-emitting element sample SAM may be analyzed based on PL light PL emitted from the light-emitting element sample SAM.

In this step (e.g., act or task) S1600, the light-emitting element sample SAM may output the PL light PL, and the PL light PL may be analyzed, so that data representing a time for which the light-emitting element sample SAM emits light and a light intensity according to a spectrum may be acquired.

In one or more embodiments, in the step (e.g., act or task) S2000 of performing the aging process, a process for degrading the light-emitting element sample SAM may be performed.

In this step (e.g., act or task) S2000, an environment capable of changing characteristics of the light-emitting element sample SAM may be formed. For example, an annealing process may be performed on the light-emitting element sample SAM, so that the light-emitting element sample SAM is provided under a relatively high temperature environment. In one or more embodiments, light with one luminance may be applied to the light-emitting element sample SAM.

In one or more embodiments, after the aging process is performed, processes substantially identical to the above-described steps S1200, S1400, and S1600 may be further performed.

In one or more embodiments, the step (e.g., act or task) S3200 of acquiring the second electrical information on the light-emitting element sample and forming the second equivalent circuit corresponding to the second electrical information, the step (e.g., act or task) S3400 of acquiring the information on the light-emitting element sample based on the second EL light, and the step (e.g., act or task) S3600 of acquiring the second PL spectrum may be performed in substantially the same process as steps S1200, S1400, and S1600 and within a constant time period.

In one or more embodiments, in the step (e.g., act or task) S3200 of acquiring the second electrical information on the light-emitting element sample and forming the second equivalent circuit corresponding to the second electrical information, electrical information on the light-emitting element sample SAM on which the aging process is performed may be analyzed.

In one or more embodiments, in the step (e.g., act or task) S3400 of acquiring the information on the light-emitting element sample based on the second EL light, optical information of the light-emitting element sample SAM on which the aging process is performed may be analyzed based on EL light EL output from the light-emitting element sample SAM on which the aging process is performed.

In this step (e.g., act or task) S3400, the light-emitting element sample SAM on which the aging process is performed may output EL light EL, and the EL light EL may be analyzed, so that current efficiency for each luminance, and quantum efficiency with respect to light emitted from the light-emitting element sample SAM on which the aging process is performed may be analyzed.

In one or more embodiments, in the step (e.g., act or task) S3600 of acquiring the second PL spectrum, the optical information of the light-emitting element sample SAM on which the aging process is performed may be analyzed based on PL light PL output from the light-emitting element sample SAM on which the aging process is performed.

In this step (e.g., act or task) S3600, the light-emitting element sample SAM on which the aging process is performed may output PL light PL, and the PL light PL may be analyzed, so that data representing a time for which the light-emitting element sample SAM on which the aging process is performed emits light and a light intensity according to a spectrum may be acquired.

In one or more embodiments, in the step (e.g., act or task) S4000 of analyzing the characteristics of the light-emitting element sample by synthesizing the optical analysis information and the electrical analysis information, characteristics of the light-emitting element sample SAM may be analyzed by synthesizing the electrical information and the optical information, which are acquired both before and after the aging process.

In one or more embodiments, it may be analyzed whether degradation of the light-emitting element sample SAM has occurred, based on the electrical information of the light-emitting element sample SAM, acquired before and after the aging process.

In one or more embodiments, changes in the current efficiency and the quantum efficiency of the light-emitting element sample SAM may be analyzed based on the optical information according to the EL light EL of the light-emitting element sample SAM acquired before and after the aging process.

In one or more embodiments, a target layer in which the degradation of the light-emitting element sample SAM occurs may be specified (determined) based on the optical information according to the PL light PL of the light-emitting element sample SAM acquired before and after the aging process.

In one or more embodiments, quantitative data regarding the degree to which the degradation of the light-emitting element sample SAM has occurred may be acquired based on the optical information according to the PL light PL of the light-emitting element sample SAM acquired before and after the aging process.

In accordance with one or more embodiments, because electrical information and optical information on the light-emitting element sample SAM can be acquired in a same process, the reliability of an analysis result can be improved, synthesis information based on the electrical information and optical information can be acquired, and the information can be complementarily interpreted. In other words, because electrical information and optical information on the light-emitting element sample SAM can be acquired in the same process, the reliability of the analysis results is significantly improved. The method allows for the simultaneous or concurrent collection of data such as resistance, capacitance, and impedance (electrical information), as well as efficiency, color coordinates, and brightness (optical information). By synthesizing this data, comprehensive synthesis information can be obtained, providing a more accurate and thorough understanding of the sample's characteristics. This combined analysis ensures that any defects or variations in the light-emitting element sample SAM can be accurately identified and characterized, leading to enhanced reliability and performance of the final display device. The complementary interpretation of electrical and optical information allows for a more detailed and reliable assessment of the sample's condition, including the identification of degradation, changes in efficiency, and the specific layers affected.

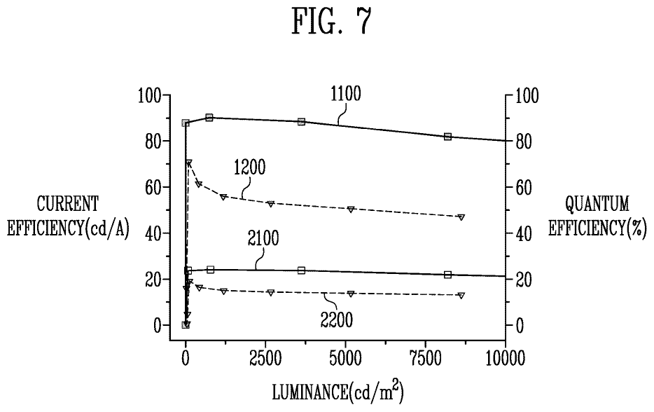

Embodiments of the method of inspecting the light-emitting element sample SAM will be described with reference to FIGS. 7 to 12. Process steps of the method of inspecting the light-emitting element sample SAM will be understood with reference to FIGS. 7 to 12.

FIG. 7 is a graph illustrating an analysis result of EL light in accordance with one or more embodiments of the present disclosure.

Referring to FIG. 7, a result obtained by analyzing EL light output from the light-emitting element sample SAM before and after the aging process (e.g., the step (e.g., act or task) S2000) is illustrated. In FIG. 7, light having a luminance of 2000 nits was irradiated onto the light-emitting element sample SAM for 30 minutes for the purpose of aging the light-emitting element sample SAM according to the aging process S2000.

A result obtained by analyzing EL light EL output from the light-emitting element sample SAM before the aging process is performed is illustrated through a (1-1)th graph line 1100 and a (2-1)th graph line 2100. The (1-1)th graph line 1100 illustrates current efficiency of the light-emitting element sample SAM before the aging process. The (2-1)th graph line 2100 illustrates quantum efficiency of the light-emitting element sample SAM before the aging process.

A result obtained by analyzing EL light EL output from the light-emitting element sample SAM after the aging process is illustrated through a (1-2)th graph line 1200 and a (2-2)th graph line 2200. The (1-2)th graph line 1200 illustrates current efficiency of the light-emitting element sample SAM after the aging process. The (2-2)th graph line 2200 illustrates quantum efficiency of the light-emitting element sample SAM after the aging process.

In accordance with one or more embodiments, it can be seen that the current efficiency and the quantum efficiency when the aging process is applied to the light-emitting element sample SAM have decreased through the analysis of the EL light EL output from the light-emitting element sample SAM.

Based on the analysis of the EL light EL output from the light-emitting element sample SAM, it may be difficult to determine which layer(s) among layers forming the light-emitting element sample SAM have undergone degradation due to the aging process. However, in one or more embodiments, as will be described in more detail later, a target layer degraded by the aging process may be determined (specified) based on the analysis of the PL light PL output from the light-emitting element sample SAM.

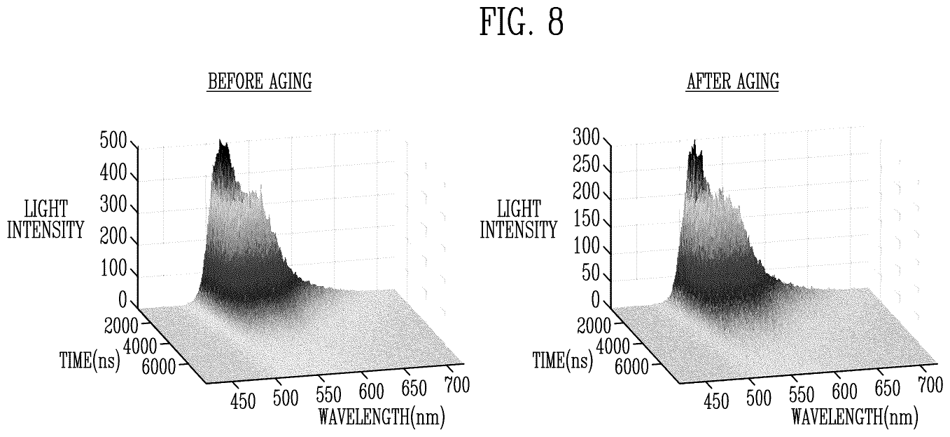

FIGS. 8 to 12 are graphs illustrating results obtained by analyzing PL light in accordance with one or more embodiments of the present disclosure. For convenience of description, in FIGS. 8 to 12, light intensity is written as relative light intensity such that numeric comparison between the graphs may be easily made.

In one or more embodiments, the light-emitting layer EML of the light-emitting element sample SAM may be manufactured to include a host and a dopant.

When the light-emitting layer EML emits light based on the host and the dopant, a wavelength of light provided by the host and a wavelength of light provided by the dopant may be specified (e.g., set or predetermined). For example, the wavelength of the light provided by the host may be determined as a first wavelength, and the wavelength of the light provided by the dopant may be determined as a second wavelength. For example, in one or more embodiments, CBP (4,4+-bis(N-carbazolyl)-1,1+-biphenyl) was used as the host of the light-emitting element sample SAM, and Ir(PPy)2Tmd (bis[2-(2-pyridinyl-κN)phenyl-κC](2,2,6,6-tetramethyl-3,5-heptanedionato-κO3,κO5)-) may be used as the dopant of the light-emitting element sample SAM. Based on this, in one or more embodiments, it may be determined that the light provided by the host in the light-emitting element sample SAM has a wavelength of about 420 nm and wavelengths adjacent thereto, and the light provided by the dopant in the light-emitting element sample SAM has a wavelength of about 550 nm and wavelengths adjacent thereto.

Referring to FIG. 8, a result obtained by analyzing PL light PL output from the light-emitting element sample SAM before and after the aging process (e.g., the step (e.g., act or task) S2000) is illustrated. As the PL light PL output from the light-emitting element sample SAM is analyzed, a spectrum representing a light intensity for each time and each wavelength is illustrated.

A result obtained by analyzing PL light PL output from the light-emitting element sample SAM before the aging process is performed is illustrated at the left side of FIG. 8. A result obtained by analyzing PL light PL output from the light-emitting element sample SAM after the aging process is performed is illustrated at the right side of FIG. 8.

In FIG. 8, light with a luminance of 100 nits was irradiated onto the light-emitting element sample SAM for 30 minutes for the purpose of aging the light-emitting element sample SAM according to the aging process. Accordingly, data (i.e., a PL spectrum) of the light intensity for each time and each wavelength of the PL light PL of the light-emitting element sample SAM before and after the aging process is provided.

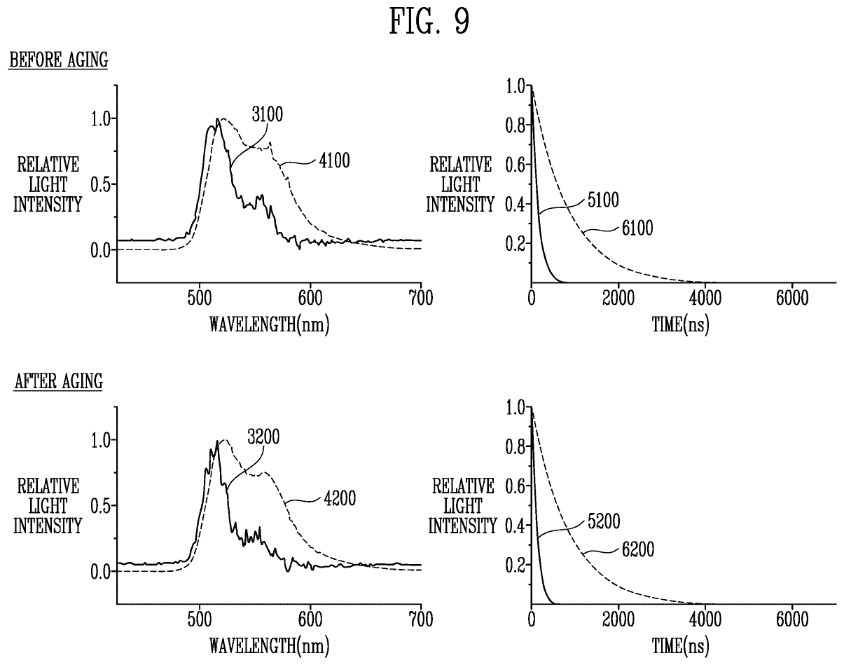

Referring to FIG. 9, in order to separate different light components of the PL light PL from a PL spectrum (i.e., the PL spectrum shown in FIG. 8) for results both before and after the aging process, data of light intensity according to wavelength may be acquired by fixing a specific time, and data of light intensity according to time may be acquired by fixing a specific wavelength band.

In the PL spectrum before the aging process is performed, relative light intensity according to wavelength with respect to the one time axis is illustrated in each of a (3-1)th graph line 3100 and a (4-1)th graph line 4100. For example, the (3-1)th graph line 3100 illustrates relative light intensity according to wavelength of a first component (i.e., a first exciton) with respect to the one time axis. The (4-1)th graph 4100 illustrates relative light intensity according to wavelength of a second component (i.e., a second exciton) with respect to the one time axis.

The light-emitting element sample SAM may output light to the outside as excitons generated as holes provided from the hole transport layer HTL and electrons provided from the electron transport layer ETL are recombined in the light-emitting layer EML to emit light.

The excitons may have different lifetimes and different emission characteristics according to their position in the light-emitting layer, for example, if the exciton is in the inside or at a surface of the light-emitting layer EML. For example, each of the (3-1)th graph line 3100 and the (4-1)th graph line 4100 may illustrate optical information of the first component and the second component, which correspond to different excitons. For example, the first component may correspond to the first exciton generated at a first position of the light-emitting layer EML. The second component may correspond to the second exciton generated at a second position different from the first position.

Because the first exciton and the second exciton provide lights at different positions, the first exciton and the second exciton may have different characteristics.

This can be seen through a trend of the relative light intensity according to wavelength for each of the (3-1)th graph line 3100 and the (4-1)th graph line 4100.

In the PL spectrum after the aging process is performed, relative light intensity according to wavelength with respect to the one time axis is illustrated through a (3-2)th graph line 3200 and a (4-2)th graph line 4200. For example, the (3-2)th graph line 3200 illustrates relative light intensity according to wavelength of the first component (i.e., the first exciton) with respect to the one time axis. The (4-2)th graph line 4200 illustrates relative light intensity according to wavelength of the second component (i.e., the second exciton) with respect to the one time axis.

Referring to the (3-1)th graph line 3100 and the (3-2)th graph line 3200, it can be seen that light intensity has decreased in a wavelength of about 550 nm and wavelengths adjacent thereto. In addition, referring to the (4-1)th graph line 4100 and the (4-2)th graph line 4200, it can be seen that light intensity has decreased in a wavelength of about 550 nm and wavelengths adjacent thereto. For example, it may be understood that, as the aging process is performed, dopant emission has been changed as the dopant of the light-emitting layer EML is degraded.

According to one or more embodiments, the (3-1)th graph line 3100 and the (3-2)th graph line 3200 illustrate optical information on the first exciton, and the first exciton may be a target exciton of the light-emitting element sample SAM. The target exciton may be an exciton provided to have an intended light characteristic if (e.g., when) the light-emitting layer EML emits light. For example, the first exciton may be an exciton generated inside the light-emitting layer EML. In one or more embodiments, the (4-1)th graph line 4100 and the (4-2)th graph line 4200 illustrate optical information on the second exciton, and the second exciton may be a parasitic exciton of the light-emitting element sample SAM. The parasitic exciton may be an exciton provided to not have an intended characteristic if (e.g., when) the light-emitting layer EML emits light. For example, the second exciton may be an exciton generated at a surface of the light-emitting layer EML, and/or the like.

As described above, in this example, because the wavelength band of the dopant emission is determined to be about 550 nm and wavelengths adjacent thereto, an exciton corresponding to a light intensity relatively concentrated on the wavelength of about 550 nm and the wavelengths adjacent thereto may be the target exciton if (e.g., when) the light intensity is formed. Similarly to this, an exciton corresponding to a light intensity relatively concentrated on a wavelength different from the wavelength of about 550 nm and the wavelengths adjacent thereto may be the parasitic exciton if (e.g., when) the light intensity is formed.

In the PL spectrum before the aging process is performed, relative light intensity according to time with respect to one wavelength axis is illustrated through a (5-1)th graph line 5100 and a (6-1)th graph line 6100. For example, the (5-1)th graph line 5100 illustrates relative light intensity according to time of the first component (e.g., the first exciton) with respect to the one wavelength axis. The (6-1)th graph line 6100 illustrates relative light intensity according to time of the second component (e.g., the second exciton) with respect to the one wavelength axis.

In the PL spectrum after the aging process is performed, relative light intensity according to time with the one wavelength axis is illustrated through a (5-2)th graph line 5200 and a (6-2)th graph line 6200. For example, the (5-2)th graph line 5200 illustrates relative light intensity according to time of the first component (i.e., the first exciton) with respect to the one wavelength axis. The (6-2)th graph line 6200 illustrates relative light intensity according to time of the second component (i.e., the second exciton) with respect to the one wavelength axis.

As described above, because different excitons have different emission characteristics, trends in which light intensities according to time decrease may be different in different excitons. For example, when referring to the (5-1)th graph line 5100 and the (6-1)th graph line 6100, and when referring to the (5-2)th graph line 5200 and the (6-2)th graph line 6200, it can be seen that different excitons have different degradation trends according to time.

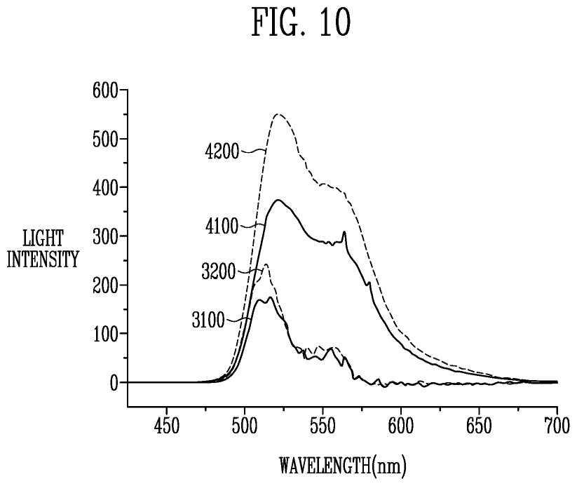

Referring to FIG. 10, the (3-1)th graph line 3100, the (3-2)th graph line 3200, the (4-1)th graph line 4100, and the (4-2)th graph line 4200, which are described with reference to FIG. 9, are illustrated together.

As described above, the (3-1)th graph line 3100 and the (3-2)th graph line 3200 may illustrate optical information provided by the first exciton as the target exciton, and the (4-1)th graph line 4100 and the (4-2)th graph line 4200 may illustrate optical information provided by the second exciton as the parasitic exciton.

In one or more embodiments, the light intensity in the (3-2)th graph line 3200 may be roughly greater than the light intensity in the (3-1)th graph line 3100. The light intensity in the (4-2)th graph line 4200 may be roughly greater than the light intensity in the (4-1)th graph line 4100. It can be seen that an increase in light intensity in the (4-1)th graph line 4100 and the (4-2)th graph line 4200, which correspond to the second exciton, is greater than an increase in light intensity in the (3-1)th graph line 3100 and the (3-2)th graph line 3200, which correspond to the first exciton. For example, a degradation degree of the light-emitting element sample SAM may be determined based on light intensity variation according to wavelength in each of the (3-1)th graph line 3100, the (3-2)th graph line 3200, the (4-1)th graph line 4100, and the (4-2)th graph line 4200.

For example, it can be seen that, as the aging process is performed, light intensity of the second exciton as the parasitic exciton is considerably increased as compared with the first exciton as the target exciton. Accordingly, it can be seen that changes in characteristics of the light-emitting element sample SAM, which occurs due to the aging process, is caused as degradation occurs in the light-emitting layer EML among the layers of the light-emitting element sample SAM.

For example, based on optical information acquired in substantially the same process as used for acquiring the electrical information, a specific position of the light-emitting element sample SAM may be specified as (determined to be) a degradation position if (e.g., when) degradation occurs in the light-emitting element sample SAM.

Accordingly, in addition to the analysis into whether degradation has occurred in the light-emitting element sample SAM, a degradation point of the light-emitting element sample SAM, and/or the like may be determined (specified), so an analysis (e.g., a thorough analysis) into the cause can be made. Consequently, the reliability of the process of inspecting the light-emitting element sample SAM may be improved, so that the reliability of the emission performance of a display device including the light-emitting element sample SAM can be improved. In one or more embodiments, defects of the light-emitting element sample SAM may be clearly analyzed, so that the display quality of the display device can be improved.

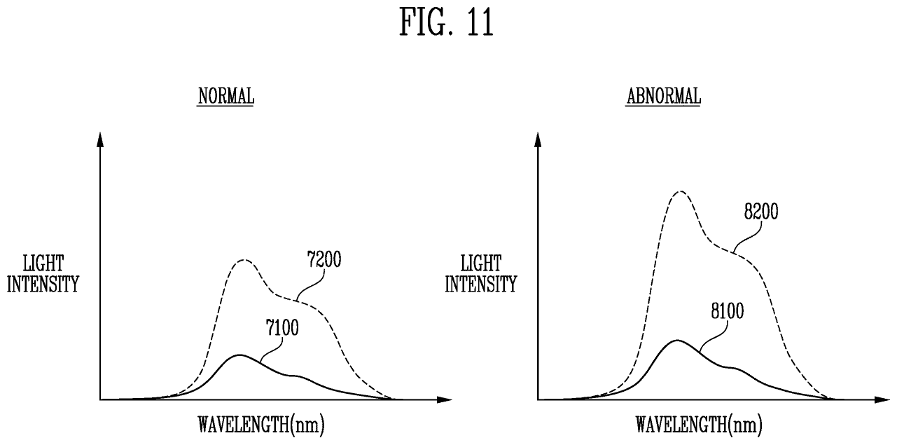

Referring to FIG. 11, an emission spectrum for excitons of a normally manufactured light-emitting element sample SAM (e.g., a light-emitting element sample manufactured under conditions generally acceptable and/or generally utilized) and an emission spectrum for excitons of an abnormally manufactured light-emitting element sample SAM (e.g., a light-emitting element sample manufactured under conditions not generally acceptable and/or generally utilized) are illustrated together.

In accordance with one or more embodiments, in the normally manufactured light-emitting element sample SAM, light intensity according to wavelength of the target exciton is illustrated in a (7-1)th graph line 7100. In the normally manufactured light-emitting element sample SAM, light intensity according to wavelength of the parasitic exciton is illustrated in a (7-2)th graph line 7200.

In accordance with one or more embodiments, in the abnormally manufactured light-emitting element sample SAM, light intensity according to wavelength of the target exciton is illustrated in a (8-1)th graph line 8100. In the abnormally manufactured light-emitting element sample SAM, light intensity according to wavelength of the parasitic exciton is illustrated in a (8-2)th graph line 8200.

In one or more embodiments, a lower area (e.g., the area under the curve or the integral) of the (7-1)th graph line 7100 may correspond to an emission amount of the target exciton in the normally manufactured light-emitting element sample SAM, and a lower area (e.g., the area under the curve or the integral) of the (7-2)th graph 7200 may correspond to an emission amount of the parasitic exciton in the normally manufactured light-emitting element sample SAM. Accordingly, a ratio of the lower area of the (7-2)th graph line 7200 with respect to the lower area of the (7-1)the graph line 7100 may be a generation ratio of the parasitic exciton with respect to the target exciton in the normally manufactured light-emitting element sample SAM.

In one or more embodiments, a lower area (e.g., the area under the curve or the integral) of the (8-1)th graph line 8100 may correspond to an emission amount of the target exciton in the abnormally manufactured light-emitting element sample SAM, and a lower area (e.g., the area under the curve or the integral) of the (8-2)th graph line 8200 may correspond to an emission amount of the parasitic exciton in the abnormally manufactured light-emitting element sample SAM. Accordingly, a ratio of the lower area of the (8-2)th graph line 8200 with respect to the lower area of the (8-1)the graph line 8100 may be a generation ratio of the parasitic exciton with respect to the target exciton in the abnormally manufactured light-emitting element sample SAM.

For example, a degradation degree of the light-emitting element sample SAM may be determined based on light intensity variation according to wavelength, and accordingly, the ratio of the parasitic exciton to the target exciton in each of the normally and abnormally manufactured light-emitting element samples SAM may be quantitatively calculated. Also, accordingly, it is quantitatively analyzed whether emission characteristics in each of the light-emitting element samples SAM have been secured within normal (e.g., generally utilized and/or generally acceptable) operational bounds.

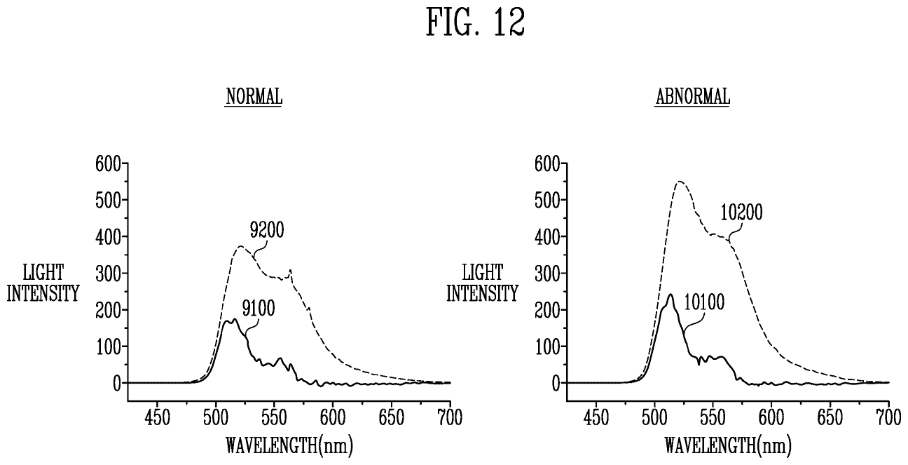

Referring to FIG. 12, an emission spectrum for excitons of a normally manufactured light-emitting element sample SAM (e.g., a light-emitting element sample manufactured under conditions generally acceptable and/or generally utilized) and an emission spectrum for excitons of an abnormally manufactured light-emitting element sample SAM (e.g., a light-emitting element sample manufactured under conditions not generally acceptable and/or generally utilized) are illustrated together.

In accordance with one or more embodiments, in the normally manufactured light-emitting element sample SAM, light intensity according to wavelength of the target exciton is illustrated in a (9-1)th graph line 9100. In the normally manufactured light-emitting element sample SAM, light intensity according to wavelength of the parasitic exciton is illustrated in a (9-2)th graph line 9200.

In accordance with one or more embodiments, in the abnormally manufactured light-emitting element sample SAM, light intensity according to wavelength of the target exciton is illustrated in a (10-1)th graph line 10100. In the abnormally manufactured light-emitting element sample SAM, light intensity according to wavelength of the parasitic exciton is illustrated in a (10-2)th graph line 10200.

In one or more embodiments, a ratio of a left peak intensity of the (9-2)th graph line 9200 with respect to a left peak intensity of the (9-1)th graph line 9100 may be calculated, and a ratio of a right peak intensity of the (9-2)th graph line 9200 with respect to a right peak intensity of the (9-1)th graph line 9100 may be calculated.

Accordingly, it can be seen that, by comparing magnitudes of the calculated ratios, the parasitic exciton has generated a higher ratio at a right peak of each of the (9-1)th graph line 9100 and the (9-2)th graph line 9200. Similarly to this, a ratio of a left peak intensity of the (10-2)th graph line 10200 with respect to a left peak intensity of the (10-1)th graph line 10100 may be calculated, and a ratio of a right peak intensity of the (10-2)th graph line 10200 with respect to a right peak intensity of the (10-1)th graph line 10100 may be calculated. Accordingly, it can be seen that, by comparing magnitudes of the calculated ratios, the parasitic exciton has generated a higher ratio at a right peak of each of the (10-1)th graph line 10100 and the (10-2)th graph line 10200.

Accordingly, a wavelength range which has influence on generation of parasitic exciton can be quantitatively analyzed, and characteristics of the light-emitting element sample SAM can be understood (e.g., thoroughly understood).

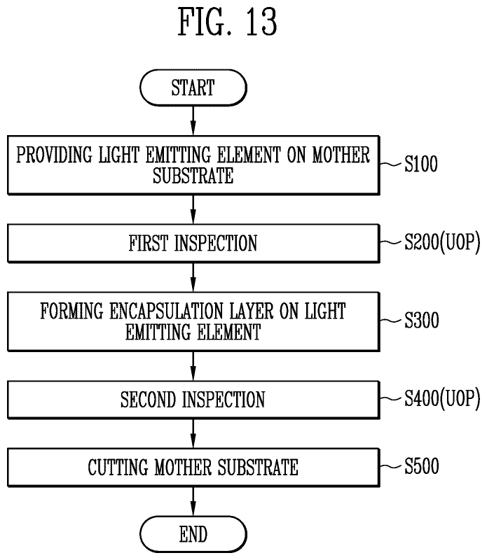

A method of manufacturing a display device, which includes the method of inspecting the light-emitting element sample SAM, in accordance with one or more embodiments of the present disclosure will be described with reference to FIGS. 13 and 14. For convenience of description, descriptions of portions overlapping with the above-described portion may be simplified or may not be repeated.

FIG. 13 is a flowchart illustrating a method of manufacturing a display device in accordance with one or more embodiments of the present disclosure.

FIG. 14 is a schematic plan view illustrating at least some process steps of the method shown in FIG. 13 in accordance with one or more embodiments of the present disclosure.

The display device in accordance with one or more embodiments of the present disclosure may be an electronic device including the light-emitting element sample SAM as a light source. The method of manufacturing the display device in accordance with one or more embodiments of the present disclosure may include the method of inspecting the light-emitting element sample SAM, as, for example, described above. For example, the method of manufacturing the display device may include unit operations UOP of the method of inspecting the light-emitting element sample SAM, which are respectively performed in a plurality of process time periods.

Hereinafter, for convenience of description, the light-emitting element sample SAM during an inspection process will be designated as a light-emitting element LD.

In one or more embodiments, the method of manufacturing the display device may include a step (e.g., act or task) S100 of providing a light-emitting element on a mother substrate, a first inspection step (e.g., act or task) S200, a step (e.g., act or task) S300 of forming an encapsulation layer on the light-emitting element, a second inspection step (e.g., act or task) S400, and a step (e.g., act or task) S500 of cutting the mother substrate 500.

Referring to FIGS. 13 and 14, in the step (e.g., act or task) S100 of providing the light-emitting element on the mother substrate, a mother substrate MS may be provided, and cells CEL each including a light-emitting element LD may be formed on the mother substrate MS. The mother substrate MS may be a base member for manufacturing the cells CEL, and may include one or more suitable materials generally available and/or generally utilized in the art. The light-emitting element LD may be manufactured on the mother substrate MS based on one or more suitable processes, such as deposition.

Referring to FIGS. 13 and 14, in the first inspection step (e.g., act or task) S200, a process of inspecting the light-emitting element LD may be performed. The first inspection step (e.g., act or task) S200 may include the above-described unit operation UOP.

In this step (e.g., act or task), characteristics of the light-emitting element LD may be analyzed based on electrical information and optical information of the light-emitting element LD. For example, in this step (e.g., act or task), the characteristics of the light-emitting element LD may be analyzed using the electrical analysis part EA and the optical analysis part OA.

Referring to FIGS. 13 and 14, in the step (e.g., act or task) S300 of forming the encapsulation layer on the light-emitting element, an encapsulation process of forming an encapsulation layer on the light-emitting element LD may be performed.

In one or more embodiments, the process of inspecting the light-emitting element LD (i.e., the first inspection step (e.g., act or task) S200) may be performed before the encapsulation layer is formed on the light-emitting element layer LD.

Accordingly, a risk of defects being caused by a process, which may occur in a process of manufacturing the light-emitting element LD, can be checked within a relatively short time.

Referring to FIGS. 13 and 14, in the second inspection step (e.g., act or task) S400, a process of inspecting the light-emitting element LD may be performed.

The second inspection step (e.g., act or task) S400 may be the above-described unit operation UOP.

In this step (e.g., act or task), characteristics of the light-emitting element LD may be analyzed based on electrical information and optical information of the light-emitting element LD. For example, in this step (e.g., act or task), the characteristics of the light-emitting element LD may be analyzed using the electrical analysis part EA and the optical analysis unit OA.

Referring to FIGS. 13 and 14, in the step (e.g., act or task) S500 of cutting the mother substrate, the mother substrate MS may be cut, and the cells CEL may be individually separated.

In one or more embodiments, the process of inspecting the light-emitting element LD (i.e., the second inspection step (e.g., act or task) S400) may be performed before a process of cutting the mother substrate MS to separate the cells CEL. Accordingly, a risk of defects being caused by a process, which may occur in the process of manufacturing the light-emitting element LD, can be checked within a relatively short time, and characteristics in manufacturing of a panel on which the cells CEL are formed is fed back (e.g., instantaneously fed back) before the cells CEL are cut, so that a risk that the of a defect occurring in and/or remaining after manufacturing of the display device can be reduced (e.g., remarkably reduced).

In one or more embodiments, the light-emitting element LD to which the inspection process is applied may be included in the manufactured display device. For example, the use or need of a separate light-emitting element sample SAM for performing the inspection process separately from the display device to be manufactured is reduced, so that process costs can be reduced. In other words, the light-emitting element LD that undergoes the inspection process may be included in the manufactured display device. This reduces the necessity of using a separate light-emitting element sample SAM for performing the inspection process separately from the display device to be manufactured, thereby reducing process costs.

Hereinafter, an electronic device 1000 including the display device manufactured according to the method of manufacturing the display device.

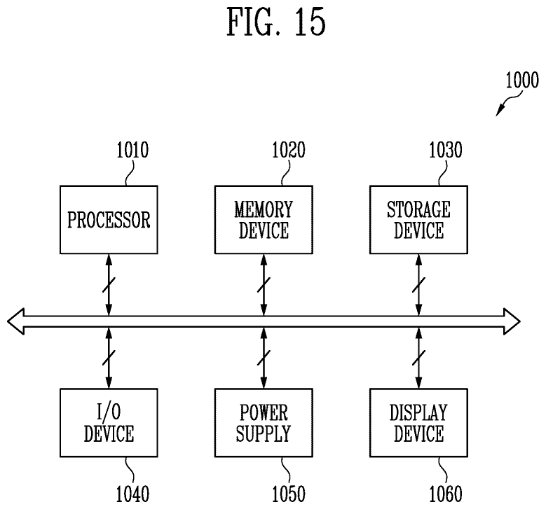

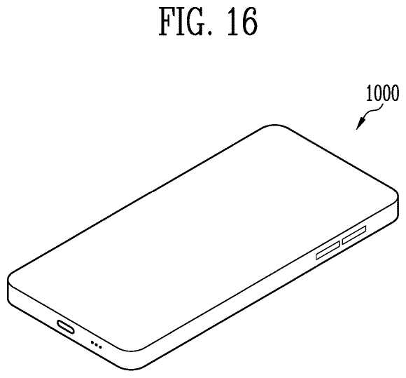

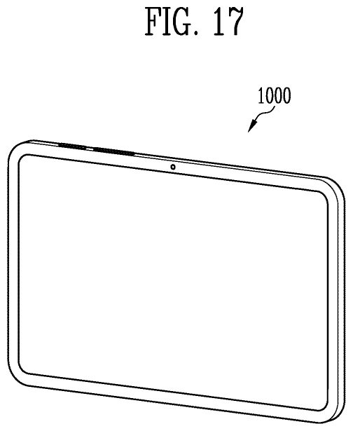

FIG. 15 is a schematic block diagram illustrating an electronic device 1000 including a display device in accordance with one or more embodiments of the present disclosure. FIG. 16 is a schematic diagram illustrating an example where the electronic device 1000 of FIG. 15 is implemented as a smartphone, according to one or more embodiments of the present disclosure. FIG. 17 is a schematic diagram illustrating an example where the electronic device 1000 of FIG. 15 is implemented as a tablet computer, according to one or more embodiments of the present disclosure.

Referring to FIGS. 15 to 17, the electronic device 1000 may include a processor 1010, a memory device 1020, a storage device 1030, an input/output (I/O) device 1040, a power supply 1050, and a display device 1060. The display device 1060 may be the display device manufactured according to method of manufacturing the display device described with reference to the preceding drawings. The electronic device 1000 may further include one or more suitable ports for communication with a video card, a sound card, a memory card, a USB device, or other systems. In one or more embodiments, as illustrated in FIG. 16, the electronic device 1000 may be implemented as a smartphone. In one or more embodiments, as illustrated in FIG. 17, the electronic device 1000 may be implemented as a tablet computer. However, the aforementioned examples are for purposes of illustration, and the electronic device 1000 is not necessarily limited to the aforementioned examples. For example, the electronic device 1000 may be implemented as a cellular phone, a video phone, a smartpad, a smartwatch, a navigation device for vehicles, a computer monitor, a laptop computer, a head-mounted display device, and/or the like.

The processor 1010 may perform specific calculations or tasks. In one or more embodiments, the processor 1010 may be a micro-processor, a central processing unit, an application processor, and/or the like. The processor 1010 may be connected to other components through an address bus, a control bus, a data bus, and/or the like. In one or more embodiments, the processor 1010 may be connected to an expansion bus such as a peripheral component interconnect (PCI) bus. In one or more embodiments, the processor 1010 may provide input image data to the display device 1060. Hence, the display device 1060 may display an image based on the input image data provided from the processor 1010.

The memory device 1020 may store data needed to perform the operation of the electronic device 1000. For example, the memory device 1020 may include non-volatile memory devices such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, and a ferroelectric random access memory (FRAM) device, and/or volatile memory devices such as a dynamic random access memory (DRAM) device, a static random access memory (SRAM) device, a mobile DRAM device, and and/or the like.

The storage device 1030 may include a solid state drive (SSD), a hard disk drive (HDD), a CD-ROM, and/or the like.

The I/O device 1040 may include input devices such as a keyboard, a keypad, a touchpad, a touch screen, and a mouse, and output devices such as a speaker and a printer. In one or more embodiments, the display device 1060 may be included in the I/O device 1040.

The power supply 1050 may supply power needed to perform the operation of the electronic device 1000. For example, the power supply 1050 may be a power management integrated circuit (PMIC). In one or more embodiments, the power supply 1050 may supply power to the display device 1060.

The display device 1060 may display an image corresponding to visual information of the electronic device 1000. The display device 1060 may be connected to other components through the buses or other communication links.

In accordance with embodiments of the present disclosure, there can be provided a method of inspecting a light-emitting element sample, an apparatus for inspecting a light-emitting element sample, a method of manufacturing a display device, and an electronic device including a display device, in which a light-emitting element has excellent or suitable light emission quality, and the operational reliability of the light-emitting element can be improved.

In accordance with embodiments of the present disclosure, there can be provided a method of inspecting a light-emitting element sample, an apparatus for inspecting a light-emitting element sample, a method of manufacturing a display device, and an electronic device including a display device, in which a degradation analysis of a light-emitting element can be performed (e.g., thoroughly performed), and a degradation position in the light-emitting element can be detected (e.g., clearly detected).

In accordance with the present disclosure, there can be provided a method of inspecting a light-emitting element sample, an apparatus for inspecting a light-emitting element sample, a method of manufacturing a display device, and an electronic device including a display device, in which the reliability of an analysis result of an inspection operation can be improved.

In accordance with the present disclosure, there can be provided a method of inspecting a light-emitting element sample, an apparatus for inspecting a light-emitting element sample, a method of manufacturing a display device, and an electronic device including a display device, in which a quantitative analysis on characteristics of a light-emitting element can be performed.

In accordance with the present disclosure, there can be provided a method of inspecting a light-emitting element sample, an apparatus for inspecting a light-emitting element sample, a method of manufacturing a display device, and an electronic device including a display device, in which process efficiency can be improved.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Further, the use of “may” when describing embodiments of the present disclosure refers to “one or more embodiments of the present disclosure. ” As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The display device, electronic device/apparatus, device for manufacturing the display device, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein.

The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A method comprising:
acquiring electrical information and optical information on a light-emitting element sample; and
analyzing the light-emitting element sample by synthesizing the electrical information and the optical information,
wherein the method is a method of inspecting the light-emitting element sample.

2. The method of claim 1, wherein, in the acquiring of the electrical information and the optical information, the electrical information and the optical information are acquired in a same inspection process.

3. The method of claim 1, wherein the acquiring of the electrical information and the optical information comprises:
applying a laser to the light-emitting element sample to cause the light-emitting element sample to emit photoluminescence (PL) light; and
applying a driving signal to the light-emitting element sample to acquire the electrical information of the light-emitting element sample and cause the light-emitting element sample to emit electroluminescence (EL) light,
wherein the electrical information comprises a resistance and a capacitance, and
wherein the laser and the driving signal are concurrently applied to the light-emitting element sample in at least a partial time period during the acquiring of the electrical information and the optical information.

4. The method of claim 3, wherein the driving signal comprises a first driving signal and a second driving signal, and
wherein the acquiring of the electrical information and the optical information comprises:
applying the first driving signal to the light-emitting element sample within a first time period;
applying the second driving signal to the light-emitting element sample within a second time period after the first time period and the second time period comprising a first sub-time period and a second sub-time period; and
applying the laser to the light-emitting element sample within the second sub-time period.

5. The method of claim 3, wherein the acquiring of the electrical information and the optical information comprises acquiring a PL spectrum of a light intensity according to a time and a wavelength based on the PL light.

6. The method of claim 3, further comprising performing an aging process on the light-emitting element sample.

7. The method of claim 6, wherein the acquiring of the electrical information and the optical information comprises:
acquiring first electrical information on the light-emitting element sample and forming a first equivalent circuit corresponding to the first electrical information, before the performing of the aging process; and
acquiring second electrical information on the light-emitting element sample and forming a second equivalent circuit corresponding to the second electrical information, after the performing of the aging process, and
wherein the analyzing of the light-emitting element sample comprises analyzing whether degradation of the light-emitting element sample has occurred.

8. The method of claim 6, wherein the acquiring of the electrical information and the optical information comprises:
acquiring information on the light-emitting element sample based on first EL light emitted from the light-emitting element sample before the performing of the aging process; and
acquiring information on the light-emitting element sample based on second EL light emitted from the light-emitting element sample after the performing of the aging process, and
wherein the analyzing of the light-emitting element sample comprises analyzing current efficiency and quantum efficiency of the light-emitting element sample.

9. The method of claim 6, wherein the acquiring of the electrical information and the optical information comprises:
acquiring a first PL spectrum based on first PL light emitted from the light-emitting element sample before the performing of the aging process; and
acquiring a second PL spectrum based on second PL light emitted from the light-emitting element sample after the performing of the aging process,
wherein the first PL spectrum and the second PL spectrum represent light intensities according to times and wavelengths of the first PL light and the second PL light, respectively, and
wherein the analyzing of the light-emitting element sample comprises specifying a target layer degraded in the light-emitting element sample.

10. The method of claim 9, wherein the analyzing of the light-emitting element sample comprises acquiring quantitative data representing a degree to which the light-emitting element sample is degraded.

11. The method of claim 9, wherein the acquiring of the electrical information and the optical information comprises separating different light components respectively from the first PL spectrum and the second PL spectrum to acquire graphs respectively corresponding to the light components.

12. The method of claim 11, wherein the light-emitting element sample comprises an electron transport layer, a hole transport layer, and a light-emitting layer between the electron transport layer and the hole transport layer, and
wherein the light components comprise a target exciton generated inside the light-emitting layer and a parasitic exciton generated at a surface of the light-emitting layer.

13. The method of claim 12, wherein the light-emitting layer comprises a host and a dopant, and
wherein the analyzing of the light-emitting element sample comprises:
predetermining a dopant wavelength of dopant light provided by the dopant; and
determining a degradation degree of the light-emitting element sample based on a light intensity variation in the dopant wavelength in the graphs.

14. An apparatus for inspecting a light-emitting element sample, the apparatus comprising:
a light source part to output a laser to the light-emitting element sample;
a sample accommodating part to accommodate the light-emitting element sample therein; and
a sample analysis part to analyze the light-emitting element sample, and
wherein the sample analysis part comprises:
an electrical analysis part to acquire electrical information on the light-emitting element sample;
an optical analysis part to acquire optical information on the light-emitting element sample; and
a synthesis analysis part to acquire synthesis analysis information by synthesizing the electrical information and the optical information.

15. The apparatus of claim 14, wherein the electrical information comprises a resistance and a capacitance of the light-emitting element sample, and
wherein the electrical analysis part is to provide a driving signal to the light-emitting element sample to cause the light-emitting element sample to emit electroluminescence (EL) light, and to apply an alternative current (AC) signal to the light-emitting element sample to acquire the electrical information.

16. The apparatus of claim 14, wherein the optical information comprises information on EL light and information on photoluminescence (PL) light, and
wherein the optical analysis part is to analyze the duration and/or light intensity of the EL light according to a spectrum, and to analyze the duration and light intensity of the PL light according to a spectrum.

17. The apparatus of claim 14, wherein the electrical analysis part is an inductance, capacitance, and resistance (LCR) meter,
the optical analysis part is a spectrometer, and
the light-emitting element sample is an organic light-emitting diode.

18. The apparatus of claim 14, further comprising:
a power supply part to supply a power signal to the light-emitting element sample,
wherein the sample accommodating part is a dark shielding box and the laser is pulse input light in a unit of picoseconds (pa) or femtoseconds (fs).

19. A method of manufacturing a display device, the method comprising:
applying a light-emitting element on a mother substrate;
performing a first inspection step after the applying of the light-emitting element, the first inspection step comprising performing an inspection process on the light-emitting element;
forming an encapsulation layer on the light-emitting element;
performing a second inspection step after the forming of the encapsulation layer, the second inspection step comprising performing an inspection process on the light-emitting element; and
cutting the mother substrate,
wherein each of the first inspection step and the second inspection step comprises a unit operation, and
wherein the unit operations each comprise:
acquiring electrical information and optical information on the light-emitting element; and
analyzing the light-emitting element by synthesizing the electrical information and the optical information.

20. The method of claim 19,
wherein the electrical information comprises a resistance and a capacitance of the light-emitting element,
wherein the optical information comprises information on electroluminescence (EL) light provided by the light-emitting element and information on photoluminescence (PL) light provided by the light-emitting element, and
wherein, in the acquiring of the electrical information and the optical information, the electrical information and the optical information are acquired in a same inspection process.
